(19) United States
(12) Patent Application Publication
(10) Pub. No.: US 2019/0029143 A1
(43) Pub. Date: Jan. 24, 2019

(54) HEAT DISSIPATION FAN WITH DETACHABLE LIGHT EMISSION UNIT

(71) Applicant: DONGGUAN CITY HANSHUO PLASTIC CO.,LTD., Guangdong Province (CN)

(72) Inventor: Hong-Hua XIE, Guangdong Province (CN)

(21) Appl. No.: 16/041,900

(22) Filed: Jul. 23, 2018

(30) Foreign Application Priority Data
Jul. 24, 2017 (TW) 106210817

(51) Int. Cl. H05K 7/20; G06F 1/20; F21V 33/00

(52) U.S. Cl. CPC H05K 7/20172; F21Y 2115/10; F21V 33/0096; G06F 1/20

(57) ABSTRACT

A heat dissipation fan with a detachable light emission unit includes a housing and a vane assembly in addition to the light emission unit. The housing has a bottom housing portion, a top housing portion, and a peripheral wall portion connected between the bottom and top housing portions. The bottom and top housing portions and the peripheral wall portion jointly surround a receiving space. Each of the bottom and top housing portions has a through hole in communication with the receiving space. The top side of the top housing portion, i.e., the side facing diametrically away from the bottom housing portion, has a lamp groove. The vane assembly is rotatably mounted in the receiving space and on the plane where the bottom housing portion lies. The light emission unit is detachably mounted in the lamp groove and, when damaged, can be detached and replaced to avoid waste of resources.

### BACKGROUND OF THE INVENTION

### 1. Technical Field

The present invention relates to the technical field of mechanical heat-dissipating devices. More particularly, the invention relates to a heat dissipation fan with a detachable light emission unit.

### 2. Description of Related Art

Every personal computer has a heat dissipation fan inside. Such a heat dissipation fan serves mainly to dissipate heat from inside a computer, thereby protecting the computer from damage caused by overheating.

In addition, people nowadays pay more and more attention to the overall look of a computer. The market, therefore, is supplied with computer chassis that are made of transparent materials, in order for their users to have a clear view of the internal structures of computers. Such a computer chassis is typically equipped with a heat dissipation fan with a light-emitting diode (LED) lamp so that, when the compute is turned on, the LED lamp of the heat dissipation fan emits light to lend a sense of modern design to the computer.

Generally, the conventional heat dissipation fans with an LED lamp have the LED lamp fixedly embedded in the fan structure. This structural design, however, makes it impossible to detach and replace the LED lamp individually when the LED strip in the lamp is damaged; the user must replace the entire heat dissipation fan with a new one, resulting in unnecessary waste of resources.

In light of the above, and in order to solve the problem that a conventional heat dissipation fan with an LED lamp must be replaced in its entirety when only the LED lamp is damaged, which constitutes a wasteful use of resources, it is imperative to provide a heat dissipation fan having a detachable light emission unit.

### BRIEF SUMMARY OF THE INVENTION

One objective of the present invention is to avoid waste of resources by solving the problem that a conventional heat dissipation fan with an LED lamp does not allow the LED lamp to be replaced.

To achieve the above objective, the present invention provides a heat dissipation fan having a detachable light emission unit. The heat dissipation fan includes a housing and a vane assembly in addition to the light emission unit.

The housing has a bottom housing portion, a peripheral wall portion, and a top housing portion. One end of the peripheral wall portion is connected to the bottom housing portion while the opposite end of the peripheral wall portion is connected to the top housing portion. The bottom housing portion, the peripheral wall portion, and the top housing portion jointly surround and thereby define a receiving space. Each of the bottom housing portion and the top housing portion has a through hole in communication with the receiving space. The top housing portion has a top side facing diametrically away from the bottom housing portion and concavely provided with a lamp groove.

The vane assembly is rotatably mounted on the plane where the bottom housing portion lies. The vane assembly is mounted in the receiving space.

The light emission unit is detachably mounted in the lamp groove.

Preferably, the heat dissipation fan further includes a lamp shade. The lamp shade is concavely provided with a receiving groove and has an opening in communication with the receiving groove. The lamp shade has an inner wall surface facing the receiving groove, and the inner wall surface has a portion corresponding to the opening and protrudingly provided with a plurality of protuberances. The light emission unit is passed through the opening and received in the receiving groove of the lamp shade, with one end of the light emission unit abutting against a bottom portion of the receiving groove and the opposite end of the light emission unit abutting against the protuberances such that the light emission unit is secured in the receiving groove. The lamp shade is mounted in the lamp groove.

Preferably, the lamp groove is an annular groove formed along the periphery of the through hole of the top housing portion, the lamp shade is annular, and both the receiving groove and the opening are annular, too.

Preferably, the top side of the top housing portion is further concavely provided with an engaging groove in communication with the lamp groove. The engaging groove has a groove wall surface facing the lamp groove and protrudingly provided with an engaging projection. Preferably, the heat dissipation fan further includes a lamp shade, and the light emission unit is received in the lamp shade. The lamp shade has an outer wall surface extended with an extension element and an engaging element. One end of the extension element is connected to the outer wall surface while the opposite end of the extension element is extended with the engaging element. The engaging element is protrudingly provided with a projecting block extending toward the groove wall surface. The projecting block abuts against the engaging projection to prevent the lamp shade from falling out of the lamp groove.

Preferably, the heat dissipation fan further includes a power supply unit mounted between the vane assembly and the bottom housing portion. The power supply unit is electrically connected to the light emission unit in order to supply electricity to the light emission unit.

The heat dissipation fan with the detachable light emission unit is so designed that a user can detach the lamp shade and replace the light emission unit when the light emission unit is damaged, thereby avoiding waste of resources.

### BRIEF DESCRIPTION OF THE SEVERAL VIEWS OF THE DRAWINGS

The objectives, features, and effects of the present invention can be better understood by referring to the following detailed description in conjunction with the accompanying drawings, in which:

FIG. 1 is a perspective view of a preferred embodiment of the present invention;

FIG. 2 is an exploded perspective view of the preferred embodiment in FIG. 1;

FIG. 3 is a sectional view of the preferred embodiment in FIG. 1;

FIG. 4 is an enlarged view of the circled area in FIG. 3;

FIG. 5 is another sectional view of the preferred embodiment in FIG. 1; and

FIG. 6 is an enlarged view of the circled area in FIG. 5.

### DETAILED DESCRIPTION OF THE INVENTION

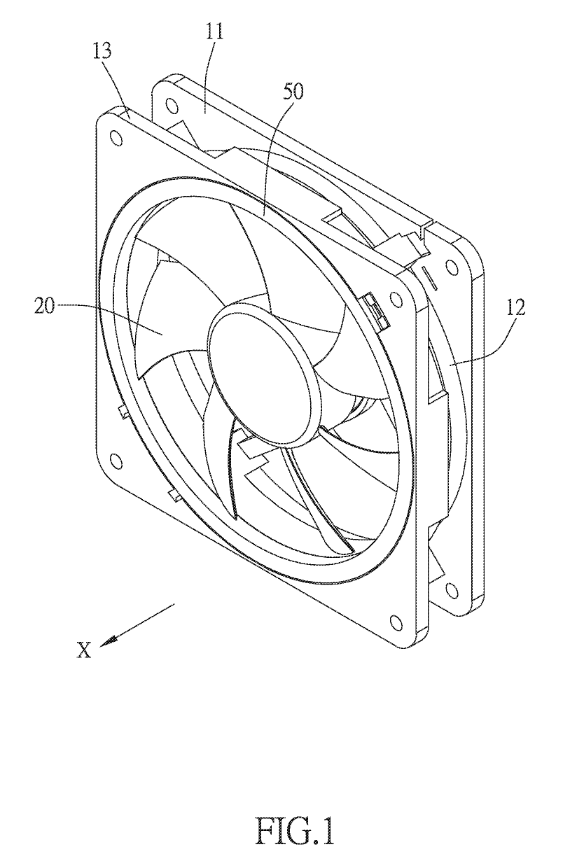

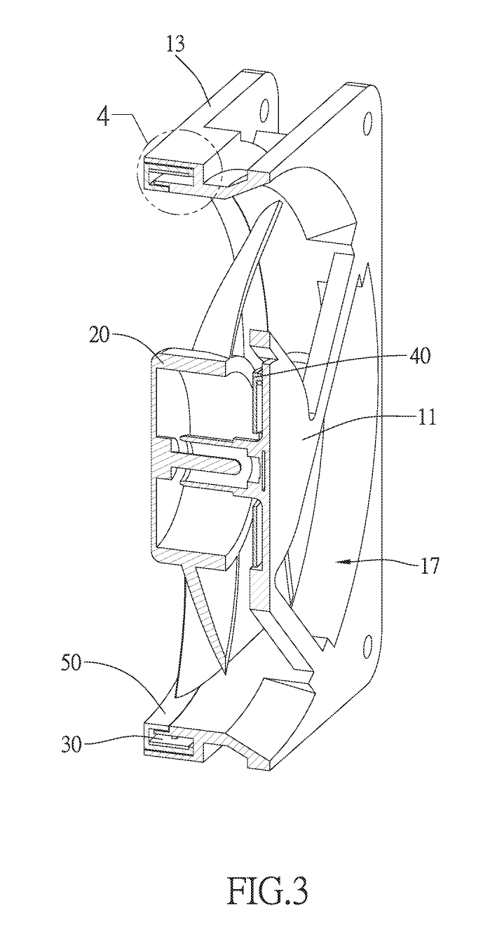

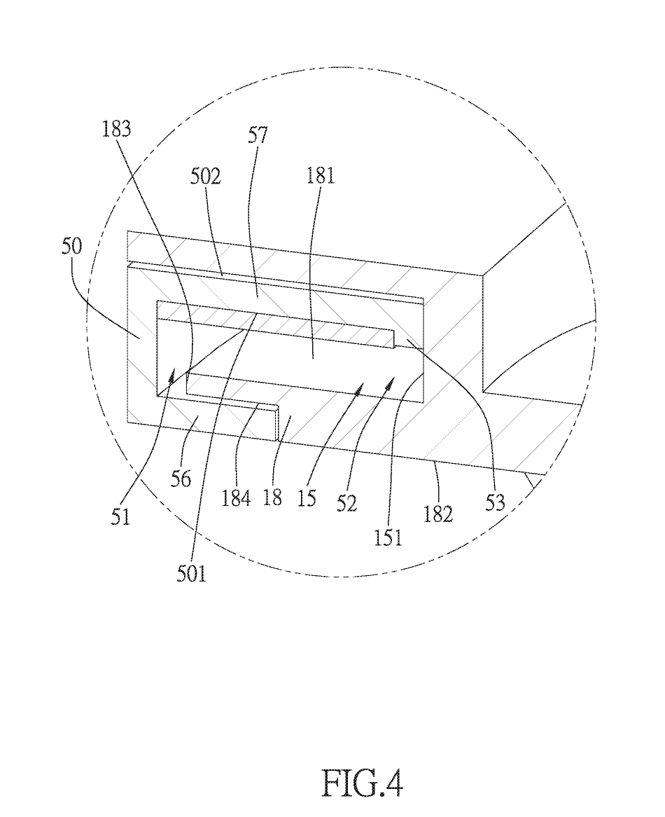

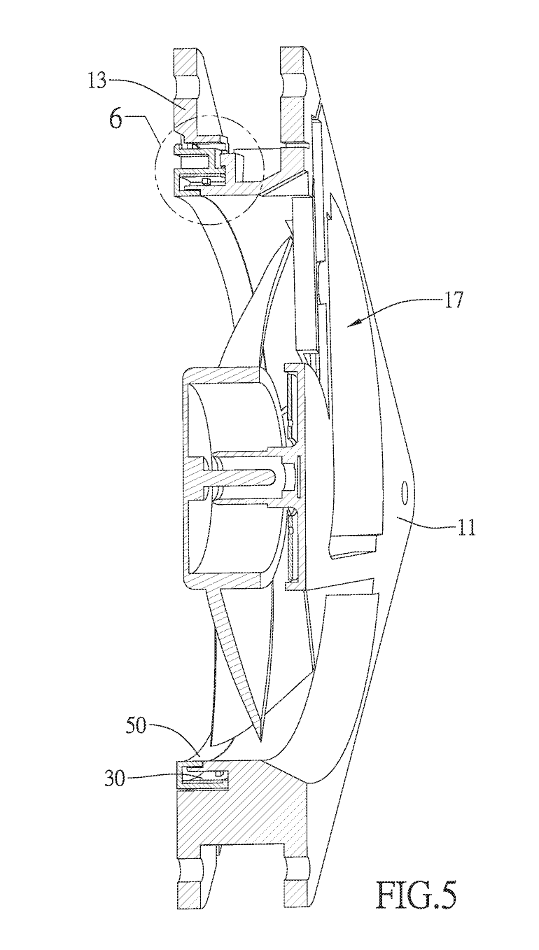

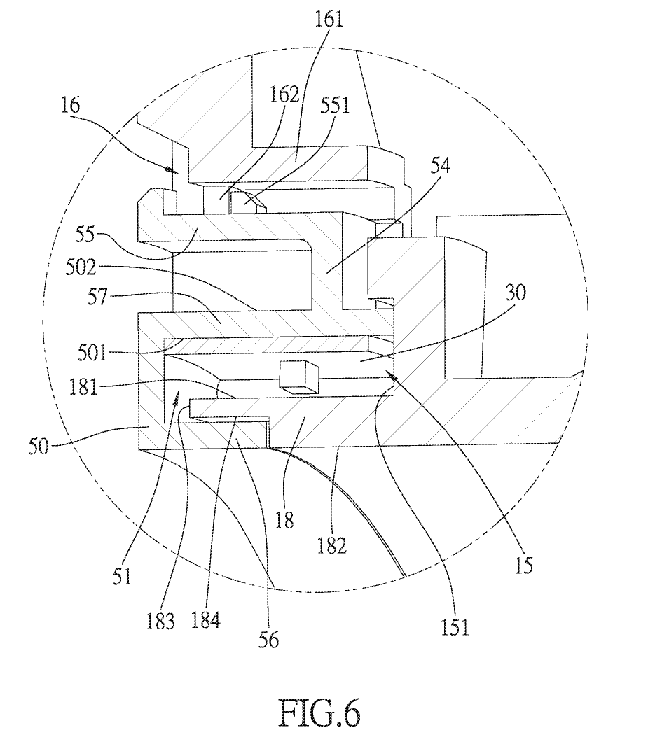

Referring to FIG. 1 to FIG. 6, the present invention provides a heat dissipation fan having a detachable light emission unit. The heat dissipation fan according to a preferred embodiment of the invention includes a housing 10, a vane assembly 20, and a light emission unit 30.

The housing 10 has a bottom housing portion 11, a peripheral wall portion 12, and a top housing portion 13. The peripheral wall portion 12 is connected to the bottom housing portion 11 at one end and is connected to the top housing portion 13 at the opposite end. The bottom housing portion 11, the peripheral wall portion 12, and the top housing portion 13 jointly surround and thereby define a receiving space 14. Each of the bottom housing portion 11 and the top housing portion 13 has a through hole 17 in communication with the receiving space 14. The top housing portion 13 has a top side 131, which is the side of the top housing portion 13 that faces diametrically away from the bottom housing portion 11. The top side 131 is concavely provided with a lamp groove 15.

In this embodiment, the lamp groove 15 is an annular groove formed along the periphery of the through hole 17 of the top housing portion 13 and has a groove bottom surface 151.

The lamp groove 15 and the through hole 17 of the top housing portion 13 are separated by an intermediate wall 18. The intermediate wall 18 has a first side 181 and a second side 182. The first side 181 and the top housing portion 13 jointly define the lamp groove 15 while the second side 182 defines the through hole 17 of the top housing portion 13. The first side 181 and the second side 182 are connected by a third side 183.

The second side 182 has a 6 184 extending toward the first side 181 such that a step is formed between the second side 182 and the third side 183.

The direction that extends from the bottom housing portion 11 to the top housing portion 13 is defined as a removing direction X.

The top side 131 of the top housing portion 13 is further concavely provided with an engaging groove 16. The engaging groove 16 is in communication with the lamp groove 15 and has a groove wall surface 161, which is the wall surface of the engaging groove 16 that faces the lamp groove 15. The groove wall surface 161 is protrudingly provided with an engaging projection 162.

The vane assembly 20 is rotatably mounted on the plane where the bottom housing portion 11 lies. Moreover, the vane assembly 20 is mounted in the receiving space 14.

The light emission unit 30 is detachably mounted in the lamp groove 15.

In this embodiment, the light emission unit 30 is an LED strip.

Preferably, the present invention further includes a power supply unit 40 mounted between the vane assembly 20 and the bottom housing portion 11. The power supply unit 40 is electrically connected to the light emission unit 30 to supply electric power to the light emission unit 30.

Preferably, the present invention further includes a lamp shade 50. The lamp shade 50 has an annular shape and is concavely provided with an annular receiving groove 51 and an annular opening 52. The opening 52 is in communication with the receiving groove 51. The lamp shade 50 has an inner wall surface 501 facing the receiving groove 51. The portion of the inner wall surface 501 that corresponds to the opening 52 is protrudingly provided with a plurality of protuberances 53. The light emission unit 30 is passed through the opening 52 and received in the receiving groove 51 of the lamp shade 50 and therefore has one end abutting against a bottom portion of the receiving groove 51 and the opposite end abutting against the protuberances 53 to secure the light emission unit 30 in the receiving groove 51. The lamp shade 50 is mounted in the lamp groove 15.

Preferably, the lamp shade 50 has an annular wall 57 with an outer wall surface 502, and the outer wall surface 502 and the inner wall surface 501 are two opposite surfaces of the annular wall 57. The outer wall surface 502 is extended with an extension element 54 and an engaging element 55. The extension element 54 extends from the outer wall surface 502. More specifically, the extension element 54 has one end connected to the outer wall surface 502 and the opposite end extended with the engaging element 55; as a result, the engaging element 55 is spaced apart from the outer wall surface 502. The engaging element 55 extends in the removing direction X, i.e., in a direction away from the groove bottom surface 151, and is protrudingly provided with a projecting block 551 extending toward the groove wall surface 161. The projecting block 551 abuts against the engaging projection 162 to prevent the lamp shade 50 from falling out of the lamp groove 15 in the removing direction X.

Preferably, the lamp shade 50 has a lamp shade wall 56. The lamp shade wall 56 and the annular wall 57 jointly surround and thereby define the receiving groove 51. The lamp shade wall 56 is fitted in the recess 184 such that the lamp shade 50 is secured in the lamp groove 15.

The configuration of the present invention and how its components are connected to one another have been disclosed above. The following paragraphs describe how the invention is used.

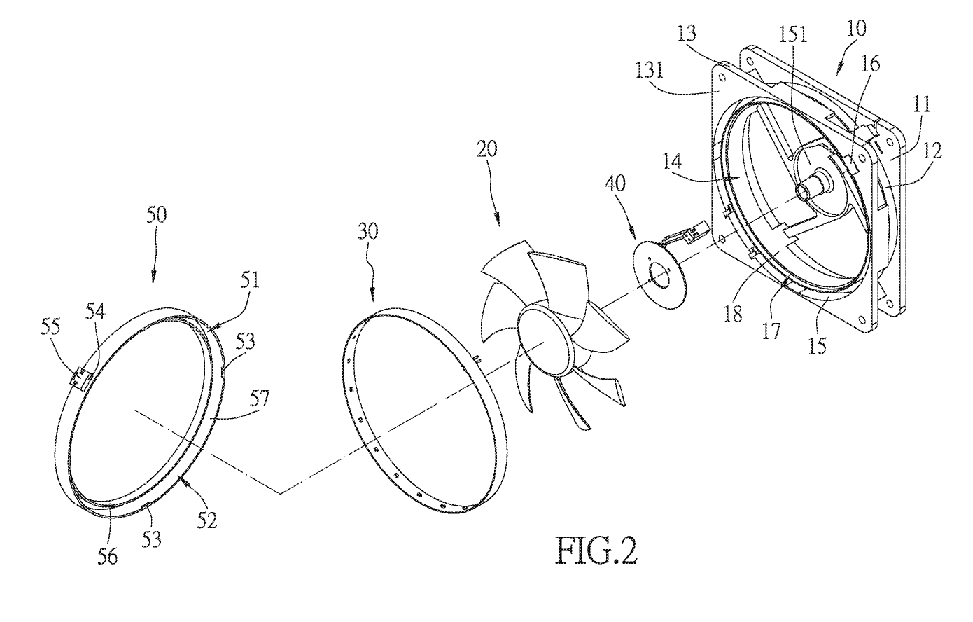

When it is desired to replace the light emission unit 30, referring to FIG. 2 to FIG. 6, the first step is to push the engaging element 55 so that the engaging element 55 is moved toward the inner wall surface 501. Then, the projecting block 551 is disengaged from the engaging projection 162 to allow the lamp shade 50 to be removed from the lamp groove 15.

After replacing the light emission unit 30 in the lamp shade 50, the lamp shade 50 is put back into the lamp groove 15, with the projecting block 551 of the engaging element 55 abutting against the engaging projection 162 on the groove wall surface 161; thus, the replacement of the light emission unit 30 is completed.

The heat dissipation fan with the detachable light emission unit as disclosed herein allows its users to detach the lamp shade 50 and replace the light emission unit 30 when the light emission unit 30 is damaged, and in consequence, the objective of avoiding waste of resources is achieved.

What is claimed is:

1. A heat dissipation fan with a detachable light emission unit, comprising:
a housing having a bottom housing portion, a peripheral wall portion, and a top housing portion, wherein the peripheral wall portion has an end connected to the bottom housing portion and an opposite end connected to the top housing portion; the bottom housing portion, the peripheral wall portion, and the top housing portion jointly surround and thereby define a receiving space; each of the bottom housing portion and the top housing portion has a through hole in communication with the receiving space; and the top housing portion has a top side facing diametrically away from the bottom housing portion and concavely provided with a lamp groove;
a vane assembly rotatably mounted on a plane where the bottom housing portion lies, wherein the vane assembly is mounted in the receiving space; and
the light emission unit, which is detachably mounted in the lamp groove.

2. The heat dissipation fan with the detachable light emission unit as recited in claim 1, further comprising a lamp shade, wherein the lamp shade is concavely provided with a receiving groove and has an opening in communication with the receiving groove, the lamp shade has an inner wall surface facing the receiving groove, the inner wall surface has a portion corresponding to the opening and protrudingly provided with a plurality of protuberances, the light emission unit is passed through the opening and received in the receiving groove of the lamp shade such that the light emission unit has an end abutting against a bottom portion of the receiving groove and an opposite end abutting against the protuberances and is thus secured in the receiving groove, and the lamp shade is mounted in the lamp groove.

3. The heat dissipation fan with the detachable light emission unit as recited in claim 2, wherein the lamp groove is an annular groove formed along a periphery of the through hole of the top housing portion, the lamp shade is annular, and both the receiving groove and the opening are annular.

4. The heat dissipation fan with the detachable light emission unit as recited in claim 1, wherein the top side of the top housing portion is further concavely provided with an engaging groove in communication with the lamp groove, and the engaging groove has a groove wall surface facing the lamp groove and protrudingly provided with an engaging projection; and wherein the heat dissipation fan further comprises a lamp shade, the light emission unit is received in the lamp shade, the lamp shade has an outer wall surface extended with an extension element and an engaging element, the extension element has an end connected to the outer wall surface and an opposite end extended with the engaging element, the engaging element is protrudingly provided with a projecting block extending toward the groove wall surface, and the projecting block abuts against the engaging projection to prevent the lamp shade from falling out of the lamp groove.

5. The heat dissipation fan with the detachable light emission unit as recited in claim 1, further comprising a power supply unit, wherein the power supply unit is mounted between the vane assembly and the bottom housing portion and is electrically connected to the light emission unit in order to supply electric power to the light emission unit.
